(19) United States
(12) Patent Application Publication
(10) Pub. No.: US 2024/0421279 A1
(43) Pub. Date: Dec. 19, 2024

(54) METHOD FOR REPAIRING DISPLAY MODULE

(71) Applicant: SAMSUNG ELECTRONICS CO.,LTD., Suwon-si (KR)

(72) Inventors: Changjoon LEE, Suwon-si (KR); Kyungwoon Jang, Suwon-si (KR); Yangsoo Son, Suwon-si (KR); Jeongyun Kim, Suwon-si (KR); Sungyong Min, Suwon-si (KR); Daesuck Hwang, Suwon-si (KR)

(73) Assignee: SAMSUNG ELECTRONICS CO.,LTD., Suwon-si (KR)

(21) Appl. No.: 18/813,979

(22) Filed: Aug. 23, 2024

Related U.S. Application Data
(63) Continuation of application No. PCT/KR2023/002049, filed on Feb. 13, 2023.

(30) Foreign Application Priority Data
Feb. 24, 2022 (KR) 10-2022-0024639
Apr. 12, 2022 (KR) 10-2022-0045227

(51) Int. Cl. H01L 33/62; H01L 25/16

(52) U.S. Cl. CPC H01L 33/62; H01L 25/167; H01L 2933/0066

(57) ABSTRACT

A method for repairing a display module on which light emitting diodes are arranged, includes: removing a defective light emitting diode from among the light emitting diodes from the display module; forming an elastic conductive pad on a panel electrode of the display module that is exposed as the defective light emitting diode is removed; transferring a new light emitting diode to the display module for electrical connection to the elastic conductive pad; covering the new light emitting diode and the elastic conductive pad with a protective layer; and curing the protective layer to maintain an elastic bond between the new light emitting diode and the elastic conductive pad.

### CROSS-REFERENCE TO RELATED APPLICATIONS

This application is a by-pass continuation application of International Application No. PCT/KR2023/002049, filed on Feb. 13, 2023, which is based on and claims priority to Korean Patent Application No. 10-2022-0024639, filed on Feb. 24, 2022, and Korean Patent Application No. 10-2022-0045227, filed on Apr. 12, 2022, in the Korean Intellectual Property Office, the disclosures of which are incorporated by reference herein in their entireties.

### BACKGROUND

### 1. Field

The disclosure relates to a method for repairing a display module, and more particularly, to a method for repairing a display module that replaces a defective micro-LED from among a plurality of micro-LEDs provided in a display module with a new micro-LED.

### 2. Description of Related Art

Light emitting diodes (LEDs) are widely used as light sources for lighting devices as well as for various display apparatuses in a variety of electronic products such as TVs, cell phones, PCs, notebook PCs, personal digital assistants (PDAs), and the like.

Recently, displays with micro-LEDs of about 100 micrometers or less in size have been developed. Compared to conventional LEDs, micro-LEDs have a faster response time, lower power, and higher brightness, making them a promising light-emitting element for next-generation displays.

If there is a defective micro-LED that fails to emit light among a plurality of micro-LEDs mounted on a display panel, the defective micro-LED is removed from the display panel and replaced with a new micro-LED.

However, the electrode pads of micro-LEDs have a fine size of about tens of micrometers or less. As a result, when a new micro-LED is mounted on a display panel, the mounting position of the new micro-LED may change when a connection part expands or contracts due to changes in ambient temperature. This has caused the electrical connection between the replacement micro-LED and the display panel to be unstable, resulting in a failure to emit light.

### SUMMARY

Provided is a method capable of repairing a display module in which a new light emitting diode replacing a defective light emitting diode elastically connects to the display panel which may maintain a physical and electrical connection to the display panel.

According to an aspect of the disclosure, a method for repairing a display module on which a plurality of light emitting diodes are arranged, the includes: removing a defective light emitting diode from among the plurality of light emitting diodes from the display module; forming an elastic conductive pad on a panel electrode of the display module that is exposed as the defective light emitting diode is removed; transferring a new light emitting diode to the display module for electrical connection to the elastic conductive pad; covering the new light emitting diode and the elastic conductive pad with a protective layer; and curing the protective layer to maintain an elastic bond between the new light emitting diode and the elastic conductive pad.

The forming the elastic conductive pad may include forming a plurality of elastic members arranged at intervals on the panel electrode, and forming a conductive layer covering the plurality of elastic members and the panel electrode.

The plurality of elastic members may be formed as a plurality of bumps arranged at intervals on the panel electrode.

The plurality of bumps may be formed of a polymeric resin having elasticity.

The polymeric resin may be a polyimide.

The plurality of elastic members may formed of a polymeric resin including a plurality of microparticles having elasticity, and the plurality of microparticles may be metallic particles having conductivity.

The plurality of microparticles may have a size of 1 μm or less.

The method may further include applying an adhesive layer to the elastic conductive pad before transferring the new light emitting diode to the display module.

The transferring the new light emitting diode may include elastically connecting the new light emitting diode to the elastic conductive pad by heat-pressing.

The conductive layer may be deposited through a chemical vapor deposition (CVD) method or a laser chemical vapor deposition (LCVD) method.

The conductive layer may be formed by applying and curing a conductive ink.

The protective layer may be formed of a transparent polymeric resin.

The method may further include forming a black matrix surrounding the new light emitting diode before forming the protective layer.

The method may further include inspecting lighting of the new light emitting diode before forming the protective layer.

The removing the defective light emitting diode may include removing a resin surrounding the defective light emitting diode by irradiating a laser to a surface of the display module, and separating the defective light emitting diode from the display module.

### BRIEF DESCRIPTION OF THE DRAWINGS

The above and other aspects, features, and advantages of certain embodiments of the disclosure are more apparent from the following description taken in conjunction with the accompanying drawings, in which:

FIG. 1 is a block diagram illustrating a display apparatus according to one or more embodiments;

FIG. 2 is a view illustrating a display panel according to one or more embodiments;

FIG. 3 is a zoomed-in view illustrating portion A shown in FIG. 2.

FIG. 4 is a view illustrating an example in which a defective light emitting diode is included in a plurality of light emitting diodes disposed in a single pixel area;

FIG. 5 is a flowchart illustrating a method for repairing a display module according to one or more embodiments;

FIG. 6 is a view illustrating panel electrodes located in a portion of a pixel area where a defective light emitting diode is removed;

FIG. 7 is a view illustrating an example in which an elastic member of an elastic conductive pad is formed on panel electrodes;

FIG. 8 is a cross-sectional view along line B-B′ shown in FIG. 7;

FIG. 9 is a view illustrating an example in which a conductive layer of an elastic conductive pad covers an elastic member and a panel electrode together;

FIG. 10 is a view illustrating an example in which an adhesive layer is applied on an elastic conductive pad;

FIG. 11 is a view illustrating an example in which new light emitting diodes are aligned for transfer to a display panel;

FIG. 12 is a view illustrating an example in which a new light emitting diode is heat-pressed onto a display panel;

FIG. 13 is a view illustrating an example in which a black matrix surrounding a new light emitting diode is formed; and

FIG. 14 is a view illustrating an example in which a new light emitting diode is covered with a protective layer.

### DETAILED DESCRIPTION

The embodiments described in the disclosure, and the configurations shown in the drawings, are only examples of embodiments, and various modifications may be made without departing from the scope and spirit of the disclosure.

Hereinafter, various embodiments will be described in greater detail with reference to the accompanying drawings. One or more embodiments described herein may be modified in various ways. Embodiments may be depicted in the drawings and described in detail in the detailed description. However, the embodiments disclosed in the accompanying drawings are only intended to facilitate understanding of the various embodiments. Therefore, the disclosure is not limited to the embodiments disclosed in the accompanying drawings, and should be understood to include all equivalents or substitutes included in the spirit and scope of the disclosure.

Terms including ordinal numbers, such as “first” or “second,” for example, may be used to describe various components, but these components are not limited by the above-described terms. The above terms are used only for the purpose of distinguishing one component from another.

Terms such as “comprise” or “have” are intended to designate the presence of features, numbers, steps, operations, components, parts, or combinations thereof described in the specification, and it should be understood that the terms are not intended to exclude in advance the presence or addition of other features, numbers, steps, operations, components, parts, or combinations thereof. When it is described that a component is “connected” or “coupled” to another component, it is understood that it may be directly connected to or coupled to the other component, but that yet another component may exist in between. On the other hand, when a component is referred to as being “directly connected” or “directly coupled” to another component, it should be understood that there are no other components in between.

The expression ‘same’ means not only complete matching but also including a degree of difference taking into account the processing error range.

A display module may include a display panel including an inorganic light-emitting diode for displaying an image. The display panel may be a flat panel display panel or a curved display panel. For example, the display panel may be mounted with a plurality of inorganic light-emitting diodes (hereinafter referred to as micro-LEDs) that are about 100 micrometers (μm) or smaller to provide increased contrast, response time, and energy efficiency compared to a liquid crystal display (LCD) that uses a backlight.

Micro-LEDs mounted on a display panel may have higher brightness, luminous efficiency, and longer lifetime than OLEDs. Micro-LEDs may be a semiconductor chip that may emit light on its own when power is supplied. Micro-LEDs have a fast response time, low power, and high brightness. For example, micro-LEDs are more efficient at converting electricity into photons compared to LCDs or OLEDs. Micro-LEDs may have a higher “brightness per watt” compared to LCD or OLED displays. Micro-LEDs may produce the same brightness with about half the energy compared to LEDs or OLEDs, which each exceeds about 100 μm in width, length, and height. Micro-LEDs have high resolution, superior color, contrast, and brightness, enabling them to accurately display a wide range of colors and provide a clear picture, even outdoors in bright sunlight. In addition, micro-LEDs are resistant to burn in and generate low heat, ensuring a long lifespan without deformation. Micro-LEDs may have a flip chip structure in which anode electrode and cathode electrode are formed on the same side, and the light-emitting surface is located on the opposite side of the side where the anode electrode and the cathode electrode are formed.

The display panel may include a glass substrate, a substrate of a family of synthetic resins having a flexibility material (for example, polyimide (PI), polyethylene terephthalate (PET), polyether sulfone (PES), polyethylene naphthalate (PEN), polycarbonate (PC), and the like), or a ceramic substrate.

A substrate may have a thin film transistor (TFT) circuit formed on a front surface, and a power supply circuit for providing power to the TFT circuit and a data driving driver, a gate driving driver, and a timing controller for controlling each driving driver may be arranged on a rear surface. A plurality of pixels arranged on the front surface of the substrate may be driven by the TFT circuit.

The substrate may not have the circuit disposed on the rear surface. The TFT circuit may be manufactured in the form of a film and attached to the front surface of the substrate (the substrate may be a glass substrate, for example).

The TFTs provided on the substrate are not limited to any particular structure or type. For example, the TFTs recited herein may be a-Si TFT (amorphous silicon) TFT, LTPS (low temperature polycrystalline silicon) TFT, LTPO (low temperature polycrystalline oxide) TFT, HOP (hybrid oxide and polycrystalline silicon) TFT, LCP (liquid crystalline polymer) TFT, OTFT (organic TFT), or graphene TFT. On the substrate, a P-type (or N-type) metal oxide semiconductor field effect transistor (MOSFET) may be applied in a Si wafer complementary metal oxide silicon (CMOS) process.

A substrate may have the front surface which is divided into an active area and an inactive area. The active area may correspond to the area occupied by the TFT layer on the front surface of the substrate, and the inactive area may correspond to the area excluding the area occupied by the TFT layer on the front surface of the substrate.

A substrate may include an edge area corresponding to a periphery. The edge area of the substrate may be the remaining area of the substrate other than the area in which the circuit of the substrate is formed. Further, the edge area of the substrate may include a portion of the front surface of the substrate, which is adjacent to a side of the substrate and a portion of the rear surface of the substrate, which is adjacent to the side of the substrate. The substrate may be formed in a quadrangle type. For example, the substrate may be formed as a rectangle or a square. The edge area of the substrate may include at least one of the four sides of the substrate.

The substrate may be a substrate without a TFT layer. The substrate may include a plurality of micro integrated circuits (micro ICs) that may act as TFTs. The substrate may be formed with wirings electrically connecting the multiple micro ICs and micro-LEDs.

The pixel drive method of the display module may be an active matrix (AM) drive method or a passive matrix (PM) drive method. The display module may form a pattern of wiring to which each micro-LED is electrically connected according to the AM drive method or PM drive method.

The display module may be applied as a single unit to wearable devices, portable devices, handheld devices, and various displays installed in electronic products or electrical devices where displays are used, and may be applied to display apparatuses such as personal computer monitors, high-definition televisions and signage (or, digital signage), or electronic displays, for example, through multiple assembly arrangements in a matrix type.

Hereinafter, with reference to the accompanying drawings, one or more embodiments will be described in detail so that those skilled in the art can practice them. One or more embodiments may be implemented in different forms, and the disclosure is not limited to the embodiments described herein. To clearly explain the present disclosure in the drawings, similar parts are given similar reference numerals throughout the specification.

Hereinafter, a display apparatus according to various embodiments will be described with reference to the accompanying drawings.

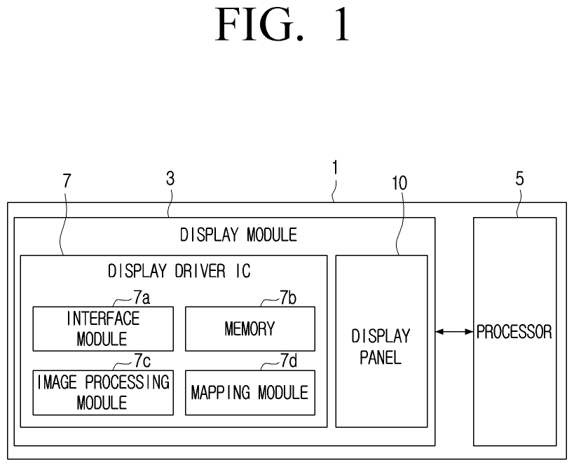

FIG. 1 is a block diagram illustrating a display apparatus according to one or more embodiments.

A display apparatus 1 may include a plurality of display modules 3. The plurality of display modules 3 may be physically connected to embody a large display (for example, a large format display, LFD).

Referring to FIG. 1, the display apparatus 1 according to one or more embodiments may include a display module 3 and a processor 5.

The display module 3 according to one or more embodiments may display various images. Here, an image is a concept that includes a still image and/or a moving image. The display module 3 may display various images, such as broadcast content, multimedia content, and the like. In addition, the display module 3 may display a user interface and an icon.

The display module 3 may include a display panel 10 and a display driver integrated circuit (DDI) 7 for controlling the display panel 10.

The display driver IC 7 may include an interface module 7a, a memory 7b (for example, a buffer memory), an image processing module 7c, or a mapping module 7d. The display driver IC 7 may receive image information including, for example, image data, or image control signals corresponding to commands for controlling the image data, from other components of the display apparatus 1 via the interface module 7a. For example, according to one or more embodiments, the image information may be received from the processor 5, such as a main processor (for example, an application processor) or a sub-processor (for example, a graphics processing unit) operating independently of the functions of the main processor.

The display driver IC 7 may communicate with a sensor module via the interface module 7a. In addition, the display driver IC 7 may store at least a portion of the received image information in the memory 7b, for example, on a frame-by-frame basis. The image processing module 7c may, for example, perform pre-processing or post-processing (for example, resolution, brightness, or scaling) of at least a portion of the image data based at least on characteristics of the image data or characteristics of the display panel 10. The mapping module 7d may generate a voltage value or a current value corresponding to the pre-processed or post-processed image data via the image processing module 7c. According to one or more embodiments, the generation of the voltage value or current value may be based at least in part on properties of the pixels of the display panel 10, for example, the arrangement of the pixels (for example, RGB stripe or pentile structure), or the size of each of the sub-pixels. At least some of the pixels of the display panel 10 may be driven, for example, based at least in part on the voltage value or the current value, such that visual information (for example, text, images, or icons) corresponding to the image data may be displayed via the display panel 10.

The display driver IC 7 may transmit a drive signal (for example, a driver drive signal or a gate drive signal) to the display based on the image information received from the processor 5.

The display driver IC 7 may display an image based on the image signal received from the processor 5. In one example, the display driver IC 7 may generate a drive signal of a plurality of sub-pixels based on an image signal received from the processor 5, and display an image by controlling light emission of the plurality of sub-pixels based on the drive signal.

The display module 3 may further include a touch circuit. The touch circuit may include a touch sensor and a touch sensor IC for controlling the touch sensor. The touch sensor IC may control the touch sensor, for example, to detect a touch input or a hovering input to a specified location on the display panel 10. For example, the touch sensor IC may detect a touch input or a hovering input by measuring a change in a signal (for example, voltage, light intensity, resistance, or charge) for a specified location on the display panel 10. The touch sensor IC may provide information (for example, location, area, pressure, or time) regarding the detected touch input or hovering input to the processor 5. According to one or more embodiments, at least a portion of the touch circuit (for example, the touch sensor IC) may be included as part of the display driver IC 7, as part of the display panel 10, or as part of another component (for example, a sub-processor) disposed externally to the display module 3.

According to one or more embodiments, the processor 5 may be implemented as a digital signal processor (DSP) for processing digital image signals, a microprocessor, a Graphics Processing Unit (GPU), an Artificial Intelligence (AI) processor, a Neural Processing Unit (NPU), or a time controller (TCON), but is not limited thereto. The processor 120 may include at least one of a central processing unit (CPU), a micro controller unit (MCU), a micro processing unit (MPU), a controller, an application processor (AP), a communication processor (CP), or an ARM processor, or may be defined as the corresponding term. In addition, the processor 5 may be implemented as a System on Chip (SoC) integrated with a processing algorithm, a large scale integration (LSI), or in the form of an application specific integrated circuit (ASIC) or a field programmable gate array (FPGA).

The processor 5 may control hardware or software components connected to the processor 5 by running an operating system or application program, and can perform various data processing and calculations. In addition, the processor 5 may load and process commands or data received from at least one of the other components onto volatile memory and store various data in a non-volatile memory.

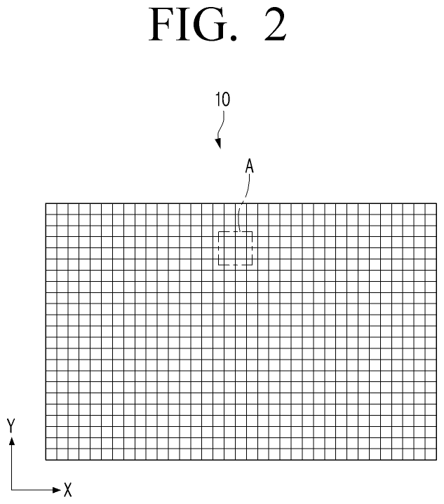

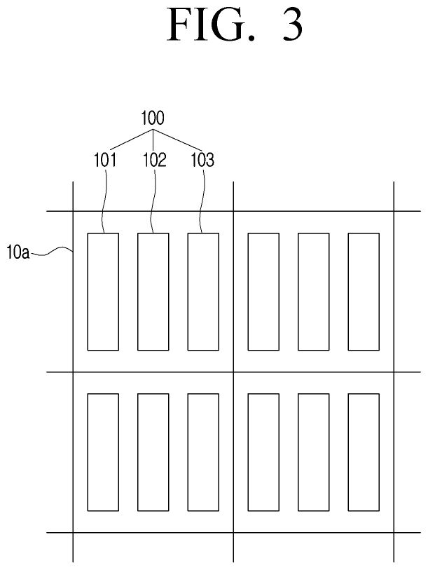

FIG. 2 is a view illustrating a display panel according to one or more embodiments, and FIG. 3 is a zoomed-in view illustrating portion A shown in FIG. 2.

Referring to FIGS. 2 and 3, the display panel 10 may include a substrate and a plurality of pixels. The substrate may include a pixel area 10a in which the plurality of pixels are arranged in a grid.

One pixel 100 may be disposed for each pixel area 10a. The one pixel 100 may include a plurality of sub-pixels. For example, the plurality of subpixels may include a first light emitting diode 101 emitting light in a red wavelength band, a second light emitting diode 102 emitting light in a green wavelength band, and a third light emitting diode 103 emitting light in a blue wavelength band. The first to third light emitting diodes 101, 102, 103 may be, for example, micro-LEDs (light emitting diodes) having a size of about 100 micrometers or less as inorganic light emitting elements. The first to third light emitting diodes 101, 102, 103 may be a flip chip type in which a first electrode pad (anode electrode pad) and a second electrode pad (cathode electrode pad) are disposed together on opposite sides of the light emitting surface.

A plurality of thin film transistors (TFTs) for driving the first to third light emitting diodes 101, 102, 103 may be disposed in portions of the single pixel area 10a that are not occupied by the first to third light emitting diodes 101, 102, 103.

The first to third light emitting diodes 101, 102, 103 may be arranged in a row at regular intervals within the single pixel area 10a, but are not limited thereto. For example, the first to third light emitting diodes 101, 102, 103 may be arranged in a shape of L or in a pentile RGBG method. The pentile RGBG method utilizes the fact that humans are less able to discriminate blue and most able to discriminate green, and arranges the number of red, green, and blue subpixels in a ratio of 1:1:2 (RGBG). The pentile RGBG method may increases yields, lower unit costs, or enable high resolution on a small screen.

The first light emitting diode 101 according to one or more embodiments may include a first semiconductor layer, a second semiconductor layer, an active layer provided between the first semiconductor layer and the second semiconductor layer, a first electrode pad, and a second electrode pad.

The first semiconductor layer, the active layer, and the second semiconductor layer may be formed using methods such as metal organic chemical vapor deposition (MOCVD), chemical vapor deposition (CVD), or plasma-enhanced chemical vapor deposition (PECVD).

The first semiconductor layer may include, for example, a p-type semiconductor layer (anode). The p-type semiconductor layer may be selected from, for example, GaAs, GaP, GaAlAs, or InGaAlP.

The active layer is the area where electrons and holes recombine, and as the electrons and holes recombine, they may transition to lower energy levels and generate light with corresponding wavelengths. The active layer may include a semiconductor material, such as amorphous silicon or poly crystalline silicon. The active layer may include an organic semiconductor material, and may be formed in a single quantum well (SQW) structure or a multi-quantum well (MQW) structure.

The second semiconductor layer may include, for example, an n-type semiconductor layer (cathode). The n-type semiconductor layer may be selected from, for example, GaAs, GaP, GaAlAs, or InGaAlP.

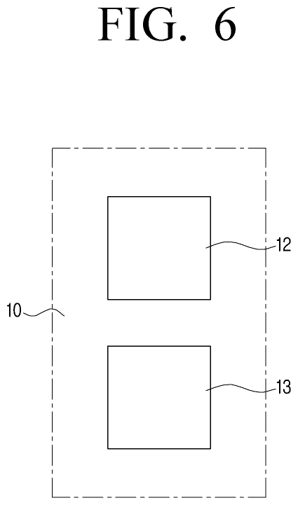

The first electrode pad is connected to the first semiconductor layer, and may be made of an opaque metal (for example, phosphorus Al, Pt, Au, Cu, or Cr). The first electrode pad may be electrically and physically connected to a first panel electrode 12 (see FIG. 6) disposed on the display panel 10 when the first light emitting diode 101 is transferred to the display panel 10.

The second electrode pad is connected to the second semiconductor layer, and may be made of an opaque metal (for example, phosphorus Al, Pt, Au, Cu, or Cr). The second electrode pad may be electrically and physically connected to a second panel electrode 13 (see FIG. 6) disposed on the display panel 10 when the first light emitting diode 101 is transferred to the display panel 10.

The structure of the second and third light emitting diodes 102, 103 may be substantially the same as the structure of the first light emitting diode 101.

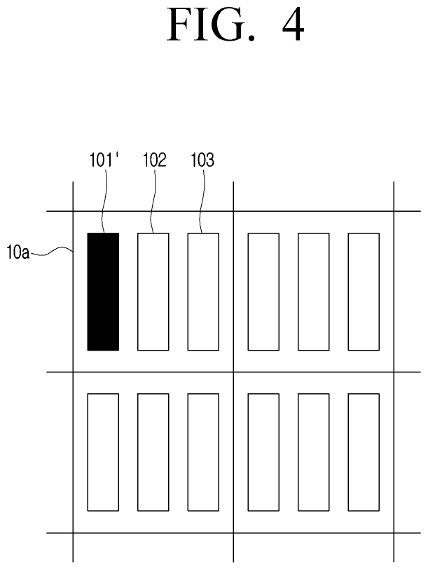

FIG. 4 is a view illustrating an example in which a defective light emitting diode is included in a plurality of light emitting diodes disposed in a single pixel area.

Referring to FIG. 4, at least one of the plurality of light emitting diodes 101′, 102, 103 disposed within the single pixel area 10a may be defective.

Hereinafter, an example of replacing a defective light emitting diode 101′ with a new light emitting diode through a method for repairing a display module according to one or more embodiments will be described.

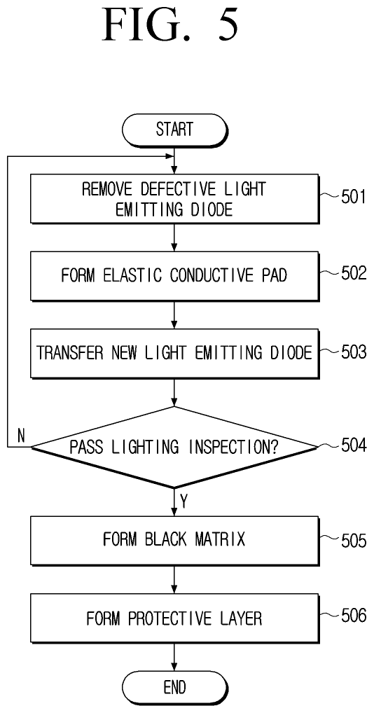

FIG. 5 is a flowchart illustrating a method for repairing a display module according to one or more embodiments.

When there is a defective light emitting diode 101′ (see shaded region in FIG. 4) among a plurality of light emitting diodes arranged in the display panel 10, the defective light emitting diode 101′ is removed from the display panel 10.

To remove the defective light emitting diode 101′ from the display panel 10, a laser is irradiated on the surface of the display panel 10 to remove the resin covering the defective light emitting diode 101′ (501 in FIG. 5).

Once the resin is removed from the surface of the display panel 10, the defective light emitting diode 101′ is physically separated from the display panel 10.

FIG. 6 is a view illustrating panel electrodes located in a portion of a pixel area where a defective light emitting diode is removed.

Referring to FIG. 6, the first panel electrode 12 and the second panel electrode 13 that were connected to a pair of electrodes of the defective light emitting diode 101′ are exposed.

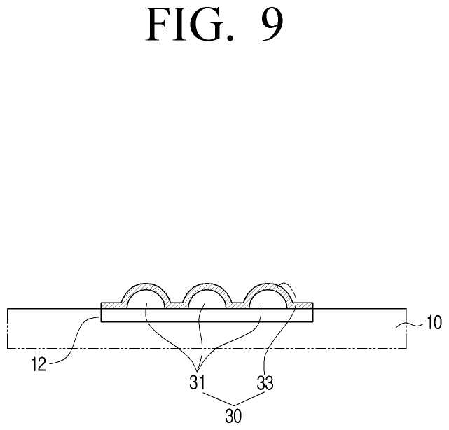

When any foreign material (for example, conductive material for connection) remains on the top surface of the first panel electrode 12 and the second panel electrode 13, it may interfere with the formation of the elastic conductive pad 30 (see FIG. 9) in a later process. The foreign material remaining on the top surface of the first panel electrode 12 and the second panel electrode 13 can be removed by chemical cleaning and/or physical cleaning process.

An elastic conductive pad for electrical and physical connection of the new light emitting diode 200 may be formed on the first panel electrode 12 and the second panel electrode 13, respectively (502 in FIG. 5).

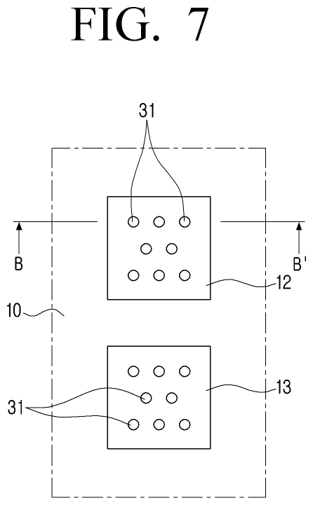

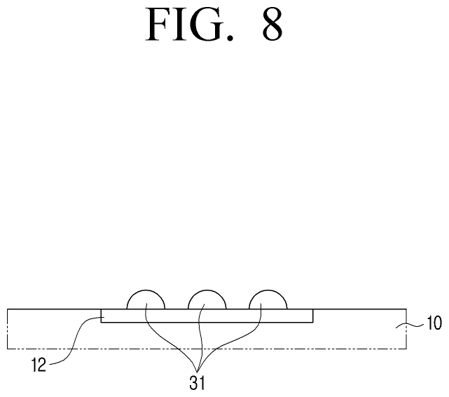

FIG. 7 is a view illustrating an example in which an elastic member of an elastic conductive pad is formed on panel electrodes, FIG. 8 is a cross-sectional view along line B-B′ shown in FIG. 7, and FIG. 9 is a view illustrating an example in which a conductive layer of an elastic conductive pad covers an elastic member and a panel electrode together.

Referring to FIGS. 7 and 8, elastic members 31 is formed on the top surface of the first panel electrode 12 and the second panel electrode 13.

The elastic members 31 may be arranged on the top surface of the first panel electrode 12 and the second panel electrode 13 at predetermined intervals as a polymeric resin is discharged in a form of fine droplets through a nozzle of a printing device.

The elastic members 31 may be made of a polymeric resin having high thermal stability, mechanical strength, and elasticity. For example, the elastic members may be polyimides.

The elastic members 31 may appear in the shape of a dot when viewed from a plane, as shown in FIG. 7. The elastic members 31 may be in the shape of a bump with a cross section having a predetermined height, as shown in FIG. 8.

The elastic members 31 are not limited to the above-described shapes, but may be straight, elliptical, or polygonal when viewed from a plane, and may be arranged on the top surface of the first panel electrode 12 and the second panel electrode 13 in various patterns.

The elastic members 31 may be a component that forms the elastic conductive pad 30 together with a conductive layer 33 (depicted in the hatched region of FIGS. 9-14) that will be described later. The elastic members 31 may adhere the conductive layer 33 to a first electrode pad 230 and a second electrode pad of the new light emitting diode 200 by elastic force to enable a reliable electrical connection.

The elastic members 31 are not limited to being formed in a bump shape. For example, the elastic members 31 may be laminated onto the first and second panel electrodes 12, 13 in a layer shape, respectively. The elastic members 31 may be made of a polymer resin including a plurality of elastic microparticles. The microparticles may be conductive metal particles having a size of 1 μm or less.

The conductive layer 33 is formed to cover the first panel electrode 12 and the elastic members 31 formed on the first panel electrode 12 together, and is formed to cover the second panel electrode 13 and the elastic members 31 formed on the second panel electrode 13 together.

The conductive layer 33 formed on the first panel electrode 12 is configured such that a portion is disposed over the elastic member 31 and the remainder is in contact with the first panel electrode 12. The conductive layer 33 formed on the second panel electrode 13 is configured such that a portion is disposed on the elastic members 31 and the remainder is in contact with the second panel electrode 13.

Accordingly, when the new light-emitting diode 200 is transferred to the display panel 10, the conductive layer 33 formed on the first panel electrode 12 may electrically connect the first electrode pad 230 of the new light-emitting diode 200, and the conductive layer 33 formed on the second panel electrode 13 may electrically connect the second electrode pad of the new light-emitting diode 200.

The conductive layer 33 may be locally deposited on the first and second panel electrodes 12, 13 via a deposition process (for example, chemical vapor deposition (CVD) or laser chemical vapor deposition (LCVD)).

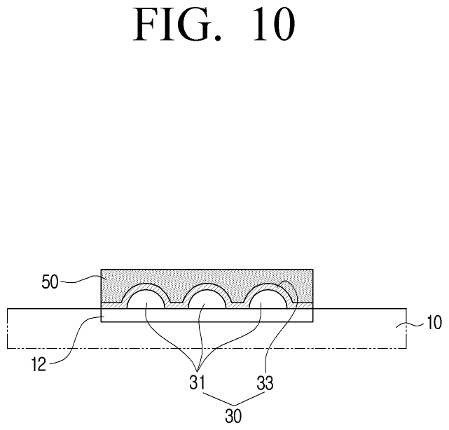

FIG. 10 is a view illustrating an example in which an adhesive layer is applied on an elastic conductive pad.

Referring to FIG. 10, before the new light emitting diode 200 is transferred to the display panel 10, an adhesive resin may be applied over the elastic conductive pads 30 formed on the first panel electrode 12 and the second panel electrode 13, respectively, to form an adhesive layer 50 (depicted in the shaded region of FIGS. 10-14).

After the adhesive layer 50 is formed on the elastic conductive pad 30, the new light emitting diode 200 is transferred to one area of the display panel 10 from which the defective light emitting diode 101′ has been removed (503 in FIG. 5).

A carrier substrate 300 and the display panel 10 may each be supported on different stages. Each stage may move the carrier substrate 300 and the display panel 10 along the X, Y, and Z axis directions, and tilt them by a predetermined angle with reference to the X, Y, and Z axes.

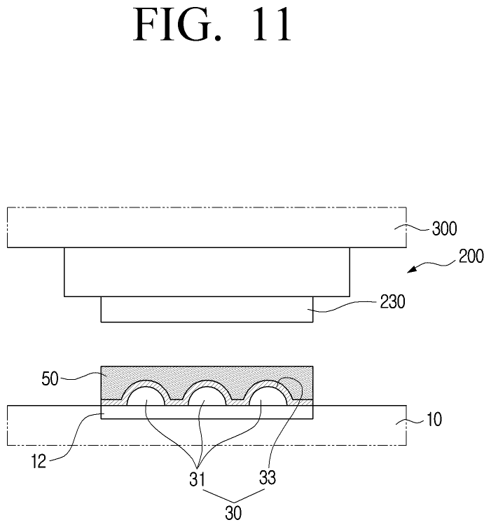

FIG. 11 is a view illustrating an example in which new light emitting diodes are aligned for transfer to a display panel.

Referring to FIG. 11, the new light emitting diode 200 may be disposed on the top side of the display panel 10 while attached to the carrier substrate 300. The carrier substrate 300 may be moved by each stage to align the new light emitting diode 200 into a transfer position.

When the new light emitting diode 200 is aligned into the transfer position, the new light emitting diode 200 may be transferred from the carrier substrate 300 to the display panel 10 in a laser transfer method (for example, laser lift-off (LLO) method).

The method of transferring the new light emitting diode 200 to the display panel 10 is not limited to the laser transfer method, but may include a stamp transfer method utilizing the difference in adhesion between a stamp and the adhesive layer 50, or a pick-and-place transfer method utilizing vacuum adsorption or electrostatic adsorption.

The new light-emitting diode 200 transferred to the display panel 10 may have a first electrode pad 230 and the second electrode pad each resting on the adhesive layer 50.

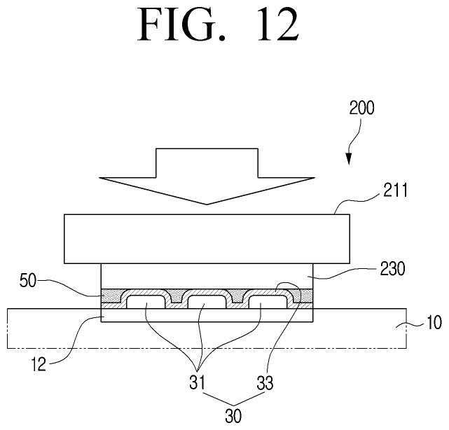

FIG. 12 is a view illustrating an example in which a new light emitting diode is heat-pressed onto a display panel.

Referring to FIG. 12, the new light emitting diode 200 is heat-pressed onto the display panel 10. As a light-emitting surface 211 of the new light-emitting diode 200 is pressed toward the display panel 10 by a pressing member, the elastic conductive pad 30 may be flattened.

At this time, the elastic members 31 of the elastic connection pad 30 have resilience in a direction opposite to the direction in which the new light emitting diode 200 is pressed by the elastic force. The conductive layer 33 of the elastic connection pad 30 may be elastically pressed against the first electrode pad 230 of the new light emitting diode 200 by the elastic force of the elastic members 31.

The conductive layer 33 may be eutectic bonded to the first electrode pad 230 of the new light emitting diode 200 by the heat provided during the heat-pressing process. In addition, the adhesive layer 50 may be cured by the heat. Accordingly, the first electrode pad 230 and the second electrode pad of the new light emitting diode 200 may be physically and firmly connected to the first panel electrode 12 and the second panel electrode 13 of the display panel 10 by the adhesive layer 50, respectively.

Similarly, the elastic conductive pad 30 formed on the second electrode pad may be elastically connected to the second electrode pad of the new light emitting diode 200.

When the new light emitting diodes 200 is transferred to the display panel 10 using a stamp transfer method or a pick-and-place transfer method, the transfer process and the heat-pressing process may be performed together.

While the new light emitting diode 200 is physically and firmly connected to the display panel 10, a lighting inspection is performed (504 in FIG. 5).

If the new light emitting diode 200 does not pass the lighting inspection due to a defective new light emitting diode or a defective connection between the new light emitting diode 200 and the display panel 10, the new light emitting diode may be removed from the display panel 10, as shown in step 501 of FIG. 5. The process corresponding to steps 502 and 503 of FIG. 5 may proceed sequentially.

When the new light-emitting diode 200 passes the lighting inspection, the post-processing may proceed.

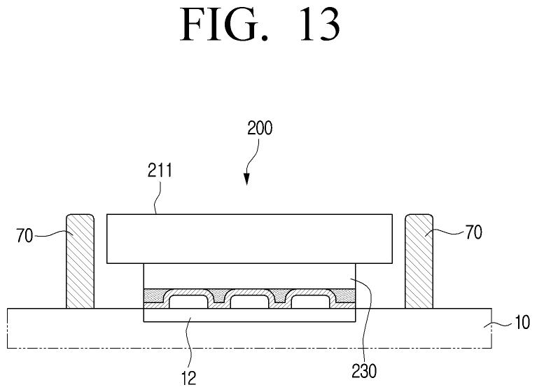

FIG. 13 is a view illustrating an example in which a black matrix surrounding a new light emitting diode is formed.

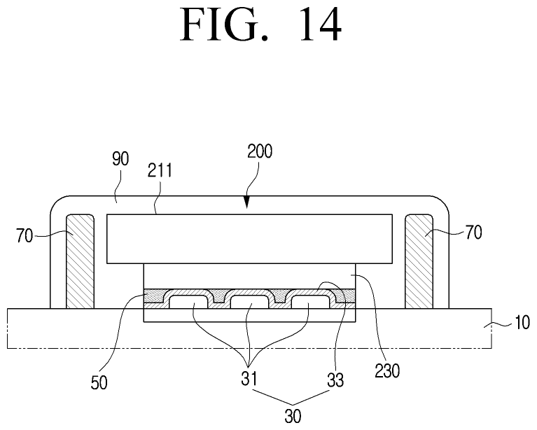

Referring to FIG. 13, a black matrix 70 (depicted in FIGS. 13-14 with hatching) may be formed by applying black ink around the new light emitting diode 200 at a predetermined height and curing the black ink (505 in FIG. 5).

The black matrix 70 may be disposed to surround the new light emitting diode 200. The black matrix 70 may be formed at a height substantially equal to the height of the other black matrices formed on the display panel 10.

FIG. 14 is a view illustrating an example in which a new light emitting diode is covered with a protective layer.

Referring to FIG. 14, the new light emitting diode 20 and the black matrix 70 may be covered together by a protective layer 90 (506 in FIG. 5).

For example, the protective layer 90 may be formed by applying a transparent polymeric resin to the top portion of the new light emitting diode 20 and the black matrix 70 and curing the same.

The protective layer 90 may be made of a transparent polymeric resin to not block or limit the amount of light emitted from the light emitting surface 211 of the new light emitting diode 200.

The protective layer 90 may maintain the elastic conductive pads 30 in a depressed state. Accordingly, the elastic members 31 may have resilience in a deformed state to elastically contact the first and second electrode pads of the new light emitting diode 200 and the conductive layer 33 corresponding to each pad.

Even if the protective layer 90 expands or contracts due to changes in temperature after the new light emitting diode is mounted on the display substrate, the electrical connection between the first and second electrode pads of the new light emitting diode 200 and the elastic conductive pad 30 corresponding thereto can be reliably maintained by the resilience of the elastic members 31 of the elastic conductive pad 30.

Although a method for repairing a display module according to one or more embodiments describes that the black matrix 70 is formed, the disclosure is not limited thereto. In some embodiments, the black matrix 70 may not be formed.

In the above description, embodiments have been illustrated and described, but the disclosure is not limited thereto, and various modifications may be made therein by those of ordinary skill in the art without departing from the scope of the disclosure. These modifications should not be understood separately from the spirit or prospect of the disclosure.

What is claimed is:

1. A method for repairing a display module on which a plurality of light emitting diodes are arranged, comprising:
removing a defective light emitting diode from among the plurality of light emitting diodes from the display module;
forming an elastic conductive pad on a panel electrode of the display module that is exposed as the defective light emitting diode is removed;
transferring a new light emitting diode to the display module for electrical connection to the elastic conductive pad;
covering the new light emitting diode and the elastic conductive pad with a protective layer; and
curing the protective layer to maintain an elastic bond between the new light emitting diode and the elastic conductive pad.

2. The method as claimed in claim 1, wherein the forming the elastic conductive pad comprises:
forming a plurality of elastic members arranged at intervals on the panel electrode; and
forming a conductive layer covering the plurality of elastic members and the panel electrode.

3. The method as claimed in claim 2, wherein the plurality of elastic members are formed as a plurality of bumps arranged at intervals on the panel electrode.

4. The method as claimed in claim 3, wherein the plurality of bumps are formed of a polymeric resin having elasticity.

5. The method as claimed in claim 4, wherein the polymeric resin is a polyimide.

6. The method as claimed in claim 2, wherein the plurality of elastic members are formed of a polymeric resin including a plurality of microparticles having elasticity; and
wherein the plurality of microparticles are metallic particles having conductivity.

7. The method as claimed in claim 6, wherein the plurality of microparticles have a size of 1 μm or less.

8. The method as claimed in claim 2, further comprising:
applying an adhesive layer to the elastic conductive pad before transferring the new light emitting diode to the display module.

9. The method as claimed in claim 2, wherein the transferring the new light emitting diode comprises elastically connecting the new light emitting diode to the elastic conductive pad by heat-pressing.

10. The method as claimed in claim 2, wherein the conductive layer is deposited through a chemical vapor deposition (CVD) method or a laser chemical vapor deposition (LCVD) method.

11. The method as claimed in claim 2, wherein the conductive layer is formed by applying and curing a conductive ink.

12. The method as claimed in claim 1, wherein the protective layer is formed of a transparent polymeric resin.

13. The method as claimed in claim 1, further comprising:
forming a black matrix surrounding the new light emitting diode before forming the protective layer.

14. The method as claimed in claim 1, further comprising:
inspecting lighting of the new light emitting diode before forming the protective layer.

15. The method as claimed in claim 1, wherein the removing the defective light emitting diode comprises:
removing a resin surrounding the defective light emitting diode by irradiating a laser to a surface of the display module; and
separating the defective light emitting diode from the display module.
